(19) United States
(12) Patent Application Publication
(10) Pub. No.: US 2007/0269646 A1
(43) Pub. Date: Nov. 22, 2007

(54) Bond termination of pores in a porous diamond dielectric material

(76) Inventors: Michael G. Haverty, Mountain View, CA (US); K. V. Ravi, Atherton, CA (US); Sadasivan Shankar, Cupertino, CA (US)

Correspondence Address: INTEL/BLAKELY, 1279 OAKMEAD PARKWAY, SUNNYVALE, CA, 94085-4040, US

(21) Appl. No.: 11/437,775

(22) Filed: May 18, 2006

(51) Int. Cl. B32B 9/00; C23C 16/00; B05D 1/32; B29C 71/04

(52) U.S. Cl. 428/312.2; 428/408; 427/249.8; 427/282; 427/532

(57) ABSTRACT

A porous diamond dielectric material having a low dielectric constant and a method of forming such a material are described herein. A porous diamond dielectric material demonstrates high mechanical strength and has a low dielectric constant because of the presence of the pores. The dielectric constant is further decreased by the conversion of the sp² type carbon bond terminations of the interior surface of the pores to sp³ type carbon bond terminations. This is accomplished by hydrogenation of the porous diamond dielectric material.

### BACKGROUND

1. Field

The present invention relates to the field of semiconductor processing and more particularly to the field of low dielectric constant dielectric materials.

2. Discussion of Related Art

Modern integrated circuits generally contain several layers of interconnect structures fabricated above a substrate. The substrate may have active devices and/or conductors that are connected by the interconnect structure.

Interconnect structures, typically comprising trenches and vias, are usually fabricated in, or on, an interlayer dielectric (ILD). It is generally accepted that, the dielectric material in each ILD should have a low dielectric constant (k) to obtain low capacitance between conductors. Decreasing this capacitance between conductors, by using a low dielectric constant (k), results in several advantages. For instance, it provides reduced RC delay, reduced power dissipation, and reduced cross-talk between interconnects. Interconnect capacitance and resistance introduces a time delay that limits the maximum rate at which data can be transferred to and from the devices within an integrated circuit.

Examples of low k dielectric materials currently used include silicon dioxide and carbon doped silicon dioxide (CDO) materials. However, a low k material, such as silicon dioxide, typically has a dielectric constant in the range of 4. As the speed of integrated circuits continue to increase, lower k dielectric materials are needed to ensure time delays do not limit the faster rates at which data is transferred between devices at. One possibility for decreasing the dielectric constant of silicon dioxide and carbon doped oxide ILDs is to further increase their porosity.

Yet, silicon dioxide at a dielectric constant of 4 exhibits a mechanical strength in the range of 80-100 GPa, while CDO's exhibits a mechanical strength in the range of 2-4 GPa. Increasing the porosity of these ILDs and lowering their mechanical strength may lead to mechanical and structural problems during subsequent wafer processing, such as during backend processing and integration, assembly and packaging. Diamond films exhibit very high mechanical strength, e.g. 1000 GPa. However, the dielectric constant of diamond films as deposited by such processes as chemical vapor deposition are typically about 5.7.

### BRIEF DESCRIPTION OF THE DRAWINGS

FIG. 1 is an illustration of a three-dimensional view of interior pore walls terminated with sp²-bonds in a porous diamond film.

FIG. 2A-2I illustrate an embodiment of a method of forming a porous diamond film having sp² terminated pore interiors.

### DETAILED DESCRIPTION

A porous diamond dielectric material having a low dielectric constant and a method of forming such a material are described herein. In the following description numerous specific details are set forth. One with ordinary skill in the art, however, will appreciate that these specific details are not necessary to practice embodiments of the invention. While certain exemplary embodiments of the invention are described and shown in the accompanying drawings, it is to be understood that such embodiments are merely illustrative and not restrictive of the current invention, and that this invention is not restricted to the specific constructions and arrangements shown and described because modifications may occur to those ordinarily skilled in the art. In other instances, well known semiconductor fabrication processes, techniques, materials, equipment, etc., have not been set forth in particular detail in order to not unnecessarily obscure embodiments of the present invention.

A porous diamond dielectric material having a low dielectric constant and a method of forming such a material are described herein. A porous diamond dielectric material has a low dielectric constant because of the presence of the pores yet still demonstrates high mechanical strength. The dielectric constant is further decreased by the conversion of the sp² type carbon bond terminations of the interior surface of the pores to sp³ type carbon bond terminations. This is accomplished by hydrogenation of the porous diamond dielectric material.

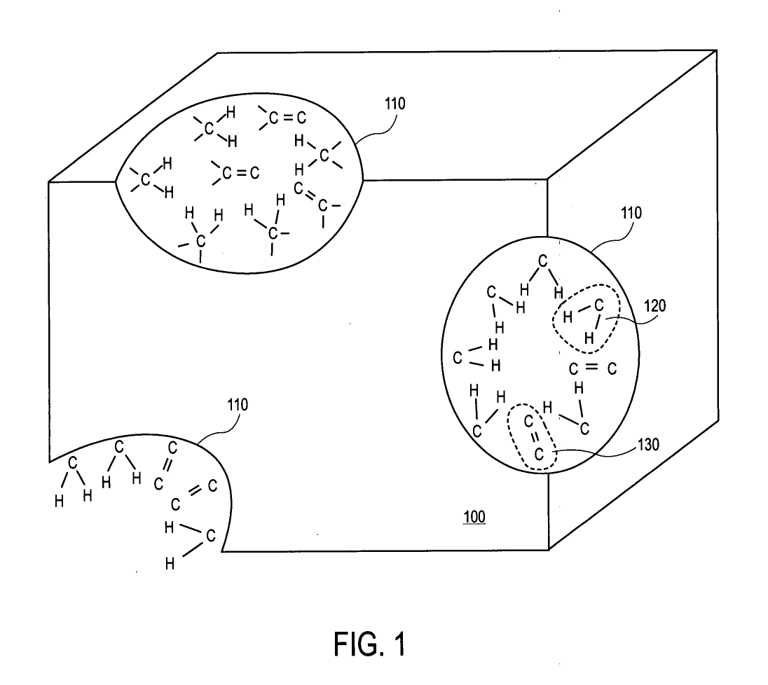

FIG. 1 illustrates the interior surface of several pores 110 within a porous diamond dielectric material 100. The interior surface of the pores 110 are terminated by a proportion of sp³ terminated carbon bonds to sp² terminated carbon bonds sufficient to lower the dielectric constant of the porous diamond film. In an embodiment, the dielectric constant of the porous diamond film is less than 2.8, and more particularly is less than 2.4. The sp³ terminated carbon bonds are the carbon atoms on the interior surface of the pores 110 that are terminated with two hydrogen atoms. The sp² terminated carbon bonds are 130. The additional dotted-line bond of 130 refers to the portion of the bond in excess of one electron pair shared in the single-bond of sp³ carbon bonds. The larger the proportion of sp² terminated carbon atoms to sp³ terminated carbon atoms, the greater the decrease of the dielectric constant of the porous diamond film. In one embodiment the proportion of sp² terminated carbon atoms to sp³ terminated carbon atoms on the interior surface of the pores within the diamond film is between 50/50 and 100/0. The porous diamond dielectric material 100 having the high proportion of sp³ terminated carbon atoms on the interior surface of the pores also has high mechanical strength. The Youngs Modulus, a measure of the mechanical strength of the material, may be greater than or equal to 4 GPa (gigaPascals.)

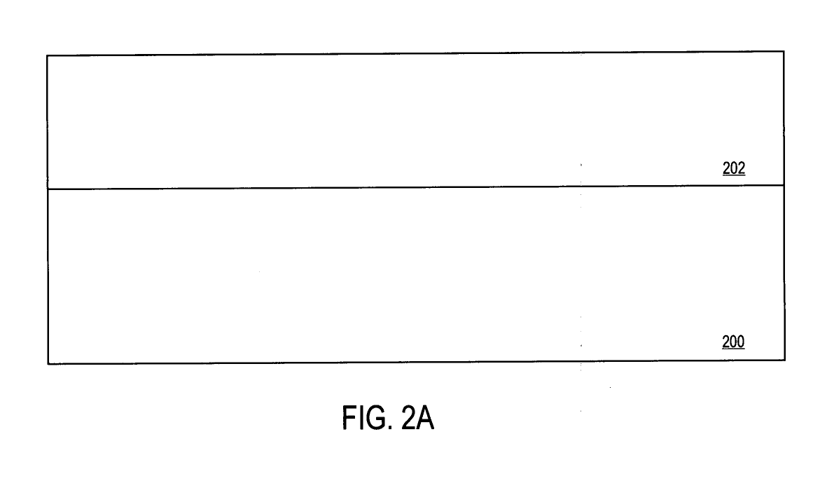

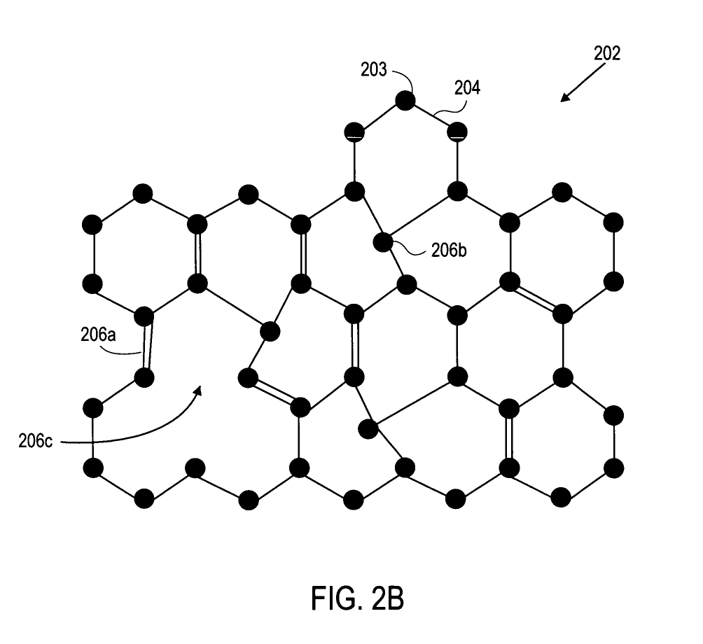

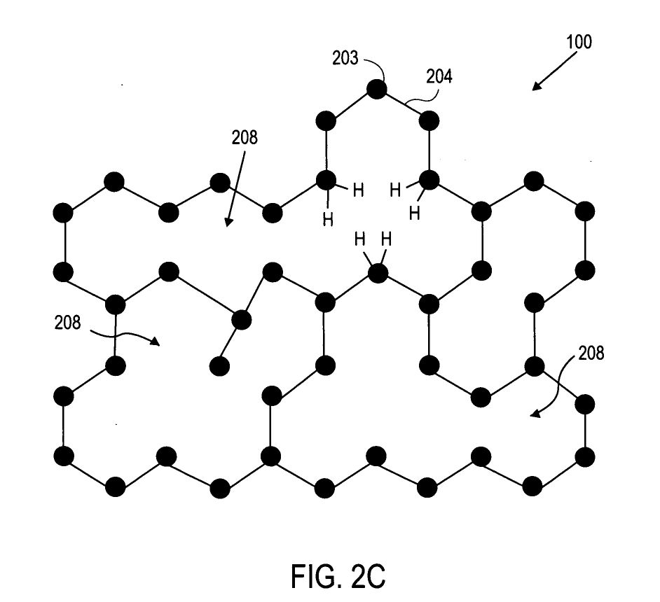

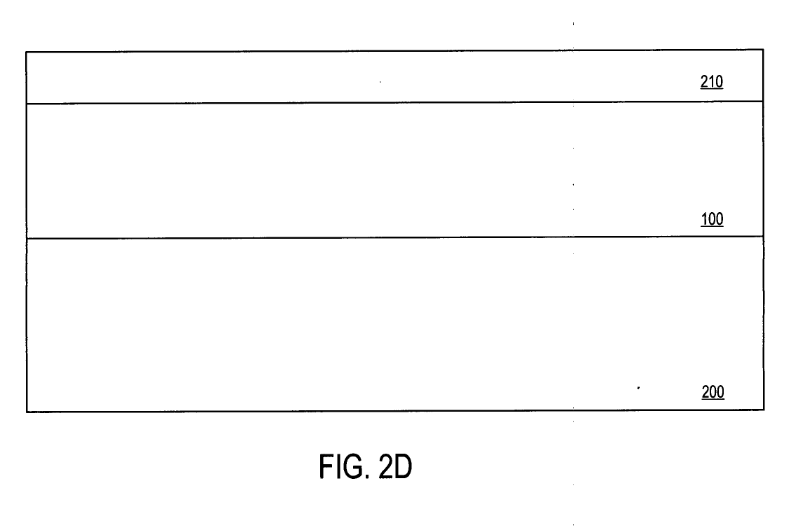

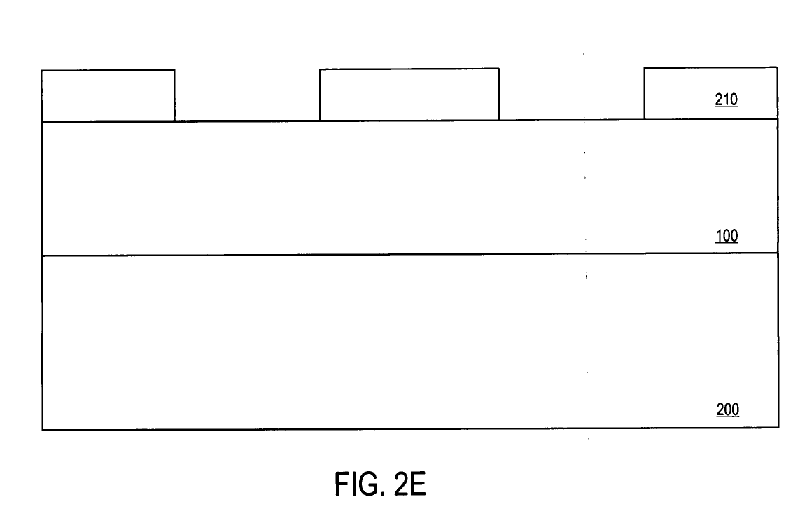

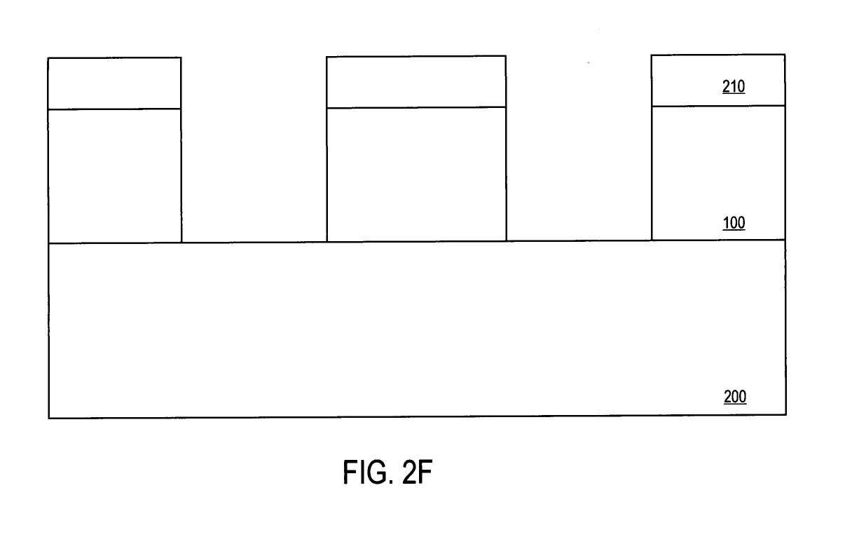

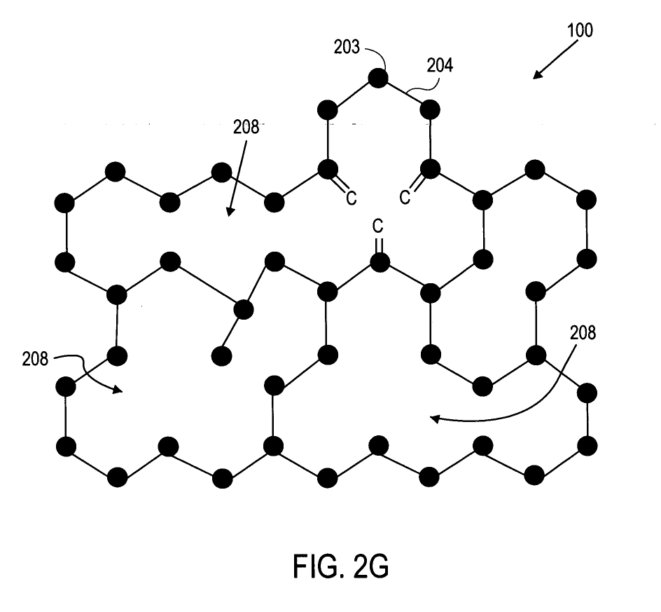

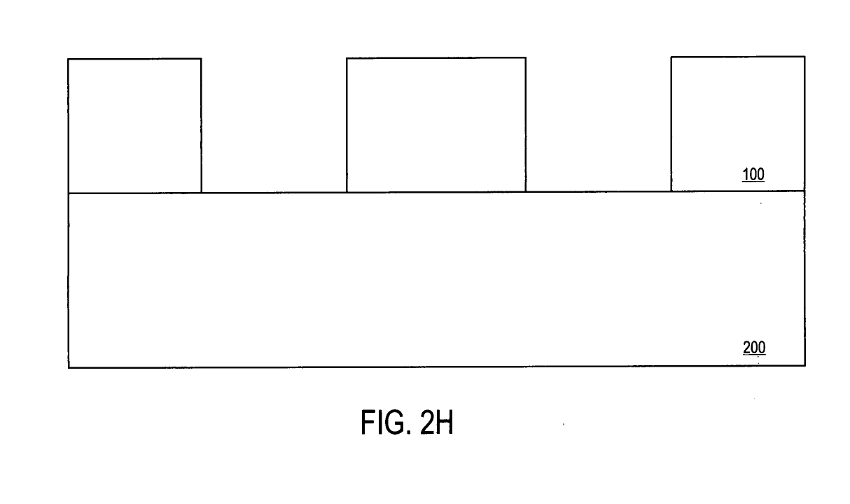

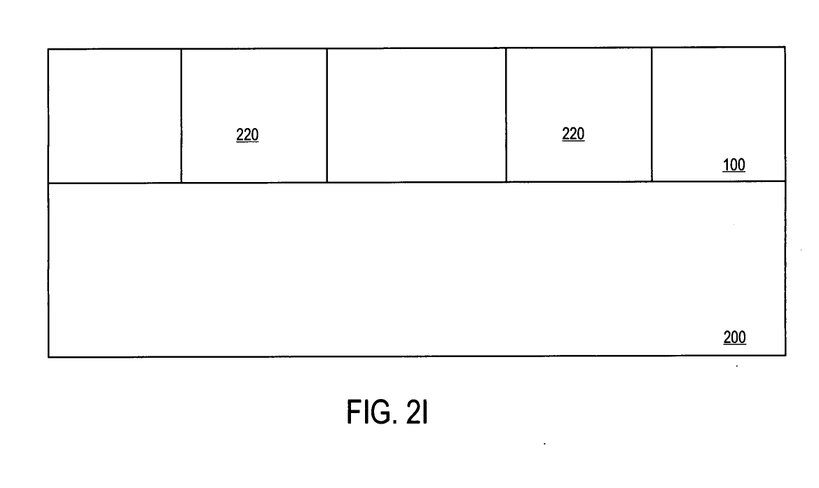

FIGS. 2A-2J illustrate an embodiment of a method and associated structures of forming a porous diamond dielectric material 100 terminated by a proportion of sp³ terminated carbon bonds to sp² terminated carbon bonds sufficient to lower the dielectric constant of the porous diamond film. FIG. 2a illustrates a cross-section of a portion of a substrate 200. The substrate 200 may be a material such as, but not limited to, silicon, silicon-on-insulator, germanium, indium, antimonide, lead telluride, indium arsenide, indium phosphide, gallium arsenide, gallium antimonide, or combinations thereof. The substrate 200 may also include various circuit elements such as transistors.

A diamond layer 202 is further formed on the substrate 200 in FIG. 2A. The diamond layer 202 may be formed utilizing conventional methods suitable for the deposition of diamond films known in the art, such as thermal chemical vapor deposition (“CVD”) or plasma-based CVD. In one embodiment, the process pressure may be in a range from about 10 to 100 Torr, a temperature of about 300 to 900 degrees, and a power between about 10 kW to about 200 kW. Methods of plasma generation may include DC glow discharge CVD, filament assisted CVD, and RF and microwave enhanced CVD.

In one embodiment, hydrocarbon gases such as CH₄, C₂H₂, fullerenes or solid carbon gas precursors may be used to form the diamond layer 202, with CH₄ (methane) being used in one particular embodiment. The hydrocarbon gas may be mixed with hydrogen gas at a concentration of at least about 10 percent hydrocarbon gas in relation to the concentration of hydrogen gas. Hydrocarbon concentrations of about 10 percent or greater generally result in the formation of a diamond layer 202 that may comprise a substantial amount of defects 206 in the crystal lattice of the diamond layer 202, such as double bonds 206a, interstitial atoms 206b and vacancies 206c, as are known in the art (FIG. 2B). The FIGS. 2b, 2c, and 2g assume that there is a 4^{th} C—C bond for each atom coming out of the plane of the figure unless that atom contains a double-bond or sp2-type bond (dotted line in addition to solid line.) It will be understood by those skilled in the art that the defects 206 may comprise any non-sp³ type forms of diamond bonding as well as any forms of anomalies, such as graphite or non-diamond forms of carbon, in the crystal lattice.

The diamond layer 202 of the present invention may comprise a mixture of bonding types between the atoms 203 of the crystal lattice of the diamond layer 202. The diamond layer 202 may comprise a mixture of double bonds 206a, also known as sp² type bonding to those skilled in the art, and single bonds 204, known as sp³ type bonding to those skilled in the art.

The defects 206 may be selectively removed, or etched, from the diamond layer 202. In one embodiment, the defects 206 may be removed by utilizing an oxidation process, for example. Such an oxidation process may comprise utilizing molecular oxygen and heating the diamond layer 202 to a temperature less than about 450 degrees Celsius. Another oxidation process that may be used is utilizing molecular oxygen and a rapid thermal processing (RTP) annealing apparatus, as is well known in the art. The defects 206 may also be removed from the diamond layer 202 by utilizing an oxygen and/or a hydrogen plasma, as are known in the art.

By selectively etching the defects 206 from the crystal lattice of the diamond layer 202, pores 208 may be formed (FIG. 2C). The pores 208 may comprise clusters of missing atoms or vacancies in the crystal lattice. The pores are formed by the selective removal of a substantial amount of the defects 206 from the lattice, since the oxidation and/or plasma removal processes will remove, or etch, the defects 206 in the diamond layer 202 while not appreciably etching the single bonds 204 of the diamond layer 202. The pores 208 lower the dielectric constant of the diamond layer 202 because the pores 208 are voids in the lattice that have a dielectric constant near one. Once the pores 208 have been formed in the diamond layer 202 a porous diamond dielectric layer 100 has been formed.

After the pores 208 have been formed, the porous diamond dielectric layer 202 may comprise a dielectric constant that may be below about 2.0, and in one embodiment is preferably below about 1.95. The presence of the rigid sp³ bonds in the porous diamond dielectric layer 202 confers the benefits of the high mechanical strength of a “pure” type diamond film with the low dielectric constant of a porous film. The strength modulus of the porous diamond dielectric layer 100 may comprise a value of above about 4 GPa. Thus, by introducing porosity, voids and other such internal discontinuities into the diamond lattice, the methods of the present invention enable the formation of a low dielectric constant, high mechanical strength, porous diamond dielectric layer 100.

In FIG. 2D, photoresist material 210 is deposited on the porous diamond dielectric layer 100. The photoresist material 210 may be deposited by a spin-on process and in an embodiment is a polymeric-based material. The photoresist material 210 will serve as a mask for etching once patterned in FIG. 2E.

The porous diamond dielectric layer 100 is then patterned by etching to form trenches, as illustrated in FIG. 2F. Other types of openings, such as vias, may also be formed. The porous diamond dielectric layer 100 is then treated by hydrogenation to increase the proportion of sp³ type carbon bond terminations relative to sp² type carbon terminations on the interior surface of at least one pore of the diamond layer 202. Hydrogenation may be performed by placing the patterned porous diamond dielectric layer 100 in a chamber in a hydrogen ambient. The porous diamond dielectric layer 100 is exposed to an amount of hydrogen sufficient to hydrogenate the interior surface of the at least one pore. The hydrogen may also be implanted into the porous diamond dielectric layer 100. In another embodiment the hydrogenation may be by molecular hydrogen (where the substrate is heated in a furnace in the presence of hydrogen) or by atomic hydrogen (using hydrogen plasma.) This is illustrated in the molecular view of the porous diamond dielectric layer 100 in FIG. 2G. The sp³ terminated carbon bonds are the carbon atoms on the interior surface of the pores 208 that are terminated with two hydrogen atoms, as illustrated previously in FIG. 2B. The sp² terminated carbon bonds are the carbon-carbon double bonds of FIG. 2D. The photoresist material 210 is left on top of the porous diamond dielectric layer 100 to ensure the hydrogenation of the inside of the trenches.

In FIG. 2H the photoresist material 210 is removed to expose the top surfaces of the porous diamond dielectric layer after the sp³ terminated carbon bonds are converted to sp² terminated carbon bonds by hydrogenation.

A conductive layer 220 is then formed within the trenches and on the top surface of the porous diamond dielectric layer 100 (FIG. 2I). The conductive layer 220 may comprise copper or aluminum. A polishing process, such as a CMP process, may be applied to the conductive layer 220 to form the substrate of FIG. 2I.

In an alternate embodiment, the porous diamond dielectric layer 100 may be formed during a hydrogen plasma etch of a silicon nitride hard mask formed on the porous diamond dielectric layer 100 before the deposition of the photoresist material 210. In this embodiment there would be no need for an extra hydrogenation step to convert the sp³ terminated carbon bonds to sp² terminated carbon bonds because it is performed during the etch of the hard mask.

As detailed above, the present invention describes the formation of diamond films that exhibit low dielectric constants (less than about 2) and superior mechanical strength. Thus, the diamond film of the present invention enables fabrication of microelectronic structures which are robust enough to survive processing and packaging induced stresses, such as during chemical mechanical polishing (CMP) and assembly processes.

Several embodiments of the invention have thus been described. However, those of ordinary skill in the art will recognize that the invention is not limited to the embodiments described, but can be practiced with modification and alteration within the scope and spirit of the appended claims that follow.

We claim:

1. A method of forming a dielectric material, comprising:
forming a diamond layer comprising an at least one pore, the at least one pore having an interior surface; and
increasing a proportion of sp³ type carbon bond terminations relative to sp² type carbon terminations on the interior surface of the at least one pore of the diamond layer.

2. The method of claim 1, wherein increasing the proportion of sp³ type carbon bond terminations relative to sp² type carbon terminations on the interior surface of the at least one pore of the diamond layer lowers the dielectric constant of the diamond layer to less than or equal to 2.8.

3. The method of claim 1, wherein increasing the proportion of sp³ type carbon bond terminations relative to sp² type carbon terminations on the interior surface of the at least one pore of the diamond layer comprises terminating the interior surface of the at least one pore with hydrogen bonds.

4. The method of claim 3, wherein terminating the interior surface of the at least one pore with hydrogen bonds comprises exposing the diamond layer to an amount of hydrogen sufficient to hydrogenate the interior surface of the at least one pore.

5. The method of claim 4, wherein exposing the diamond layer to the amount of hydrogen sufficient to hydrogenate the interior surface of the at least one pore comprises exposing the diamond layer to molecular hydrogen.

6. The method of claim 4, wherein exposing the diamond layer to the amount of hydrogen sufficient to hydrogenate the interior surface of the at least one pore comprises exposing the diamond layer to atomic hydrogen.

7. The method of claim 4, wherein terminating the interior surface of the at least one pore with hydrogen bonds comprises implanting hydrogen into the diamond layer.

8. The method of claim 1, further comprising patterning the diamond layer prior to increasing the proportion of sp³ type carbon bond terminations relative to sp² type carbon terminations on the interior surface of the at least one pore of the diamond layer.

9. The method of claim 1, wherein increasing the proportion of sp³ type carbon bond terminations relative to sp² type carbon terminations on the interior surface of the at least one pore of the diamond layer comprises creating a ratio of sp³ to sp² terminations in the approximate range of 50/50 and 100/0.

10. The method of claim 1, further comprising:
forming a patterned silicon nitride hard mask on the diamond layer; and
etching the diamond layer with a plasma of an oxygen species from which atomic hydrogen is produced in an amount sufficient to hydrogenate the interior surface of the at least one pore.

11. A method of forming a microelectronic device, comprising:
forming a porous diamond film on a substrate, the porous diamond film having at least one pore having an interior surface;
patterning the porous diamond film; and
exposing the porous diamond film to a plasma of atomic hydrogen to hydrogenate more than 50% of the interior surface of the at least one pore after patterning the porous diamond film.

12. The method of claim 11, wherein hydrogenating the interior surface of the at least one pore lowers the dielectric constant of the porous diamond film to less than 2.4.

13. The method of claim 11, wherein forming the porous diamond film on a substrate comprises exposing the substrate to a gas comprising a hydrocarbon and hydrogen to form a hybrid film comprising diamond and graphite portions and etching the graphite portions to form pores.

14. A dielectric material, comprising:
a porous diamond material having an at least one pore having a interior surface, wherein the interior surface is terminated by a proportion of sp³ terminated carbon bonds to sp² terminated carbon bonds sufficient to lower the dielectric constant of the porous diamond film.

15. The dielectric material of claim 14, wherein the dielectric constant of the porous carbon material is less than or equal to 2.4.

16. The dielectric material of claim 14, wherein the Young's Modulus of the porous carbon material is greater than or equal to 4 GPa.

17. The dielectric material of claim 14, wherein the plurality of pores is terminated by the proportion of sp³ carbon bond termination to ^{sp2} carbon bond termination within the approximate range of 50/50 to 100/0.
